(19) United States
(12) Patent Application Publication
(10) Pub. No.: US 2015/0070981 A1
(43) Pub. Date: Mar. 12, 2015

(54) MAGNETORESISTANCE ELEMENT AND MAGNETORESISTIVE MEMORY

(71) Applicant: Yoshinori KUMURA, Seoul (KR)

(72) Inventor: Yoshinori KUMURA, Seoul (KR)

(21) Appl. No.: 14/160,238

(22) Filed: Jan. 21, 2014

Related U.S. Application Data
(60) Provisional application No. 61/874,836, filed on Sep. 6, 2013.

(51) Int. Cl. H01L 27/22; G11C 11/16

(52) U.S. Cl. CPC H01L 27/228; G11C 11/1675
USPC 365/158; 257/295

(57) ABSTRACT

According to one embodiment, a magnetoresistance element includes a spin valve structure portion formed on a substrate and a tunnel magnetic junction structure portion formed on a part of the spin valve structure portion. The spin valve structure portion is formed by having a nonmagnetic layer sandwiched between first and second ferromagnetic layers. Further, the tunnel magnetic junction structure portion includes the second ferromagnetic layer, a tunnel barrier layer formed on a part of the second ferromagnetic layer and a third ferromagnetic layer formed on the tunnel barrier layer.

### CROSS-REFERENCE TO RELATED APPLICATIONS

This application claims the benefit of U.S. Provisional Application No. 61/874,836, filed Sep. 6, 2013, the entire contents of which are incorporated herein by reference.

### FIELD

Embodiments described herein relate generally to a magnetoresistance element and a magnetoresistive memory using the same.

### BACKGROUND

Recently, much attention and expectation surrounds a magnetoresistive random access memory (MRAM) of large capacity using a magnetic tunnel junction (MTJ). Generally, the memory cell of the MRAM has a structure obtained by laminating a plurality of ferromagnetic layers and barrier layer. Since the holding force becomes larger if the MTJ element size is reduced in the conventional MRAM in which data is written in a magnetic field created by a wire current, a current required for data writing tends to become larger. Therefore, it is difficult to simultaneously attain miniaturization of the cell size and a reduction in the current for the purpose of achieving large capacity.

As a write system that solves the above problem, a spin transfer torque MRAM using a spin transfer torque (STT) writing system is proposed. In the spin transfer torque MRAM, an information writing process is performed by passing a current in an MTJ element to change the direction of magnetization of a free layer according to the direction of the current. However, in the spin transfer torque MRAM of this type, there occurs a problem that a write current cannot be sufficiently obtained and the reliability of the barrier layer is lowered. Further, there also occurs a problem that a sufficiently large signal amount cannot be obtained.

### BRIEF DESCRIPTION OF THE DRAWINGS

FIG. 1 is a cross-sectional view showing the schematic configuration of a magnetoresistive memory according to a first embodiment.

FIG. 2 is a cross-sectional view showing the configuration of an enlarged main portion of the magnetoresistive memory in FIG. 1.

FIG. 3 is a schematic view showing a current path at the write operation time of the magnetoresistive memory in the first embodiment.

FIG. 4 is a schematic view showing a current path at the read operation time of the magnetoresistive memory in the first embodiment.

FIG. 5 is a cross-sectional view showing the schematic configuration of a magnetoresistive memory according to a second embodiment.

FIG. 6 is a cross-sectional view showing the schematic configuration of a magnetoresistive memory according to a third embodiment.

FIG. 7 is a cross-sectional view showing the configuration of an enlarged main portion of the magnetoresistive memory in FIG. 6.

FIG. 8 is a schematic view showing a current path at the “1” write operation time of the magnetoresistive memory in the third embodiment.

FIG. 9 is a schematic view showing a current path at the “0” write operation time of the magnetoresistive memory in the third embodiment.

FIG. 10 is a cross-sectional view showing the schematic configuration of a magnetoresistive memory according to a fourth embodiment.

FIGS. 11A, 11B are circuit configuration diagrams showing a magnetoresistive memory according to a fifth embodiment.

FIG. 12 is a circuit configuration diagram showing a magnetoresistive memory according to a sixth embodiment.

### DETAILED DESCRIPTION

In general, according to one embodiment, a magnetoresistance element comprises a spin valve structure portion formed on a substrate and a tunnel magnetic junction structure portion formed on a part of the spin valve structure portion. The spin valve structure portion is formed by having a nonmagnetic layer sandwiched between first and second ferromagnetic layers. Further, the tunnel magnetic junction structure portion includes the second ferromagnetic layer, a tunnel barrier layer formed on a part of the second ferromagnetic layer and a third ferromagnetic layer formed on the tunnel barrier layer.

Next, embodiments are explained in detail with reference to the accompanying drawings.

### First Embodiment

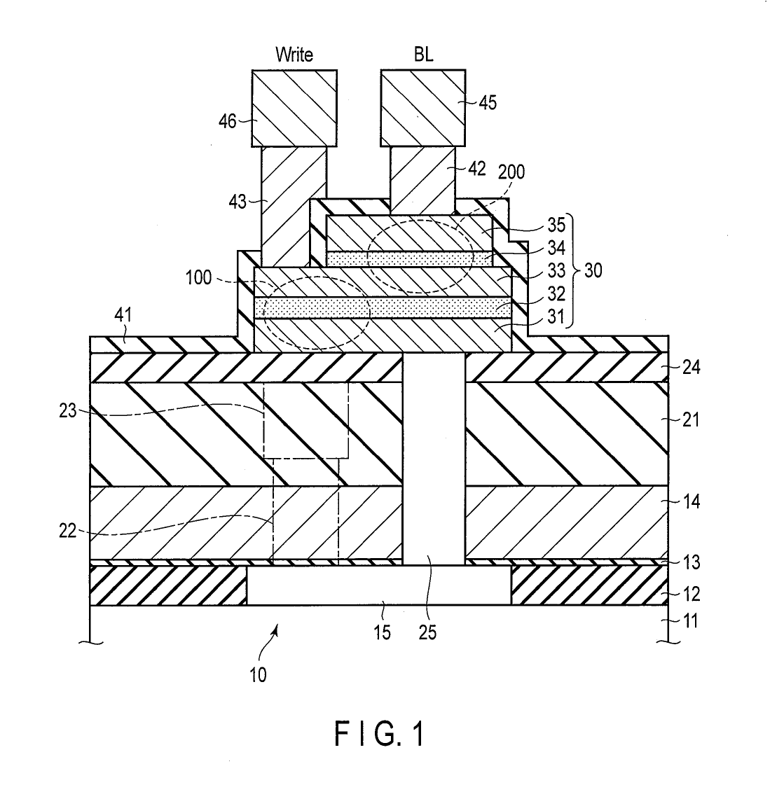

FIG. 1 is a cross-sectional view showing the schematic configuration of a magnetoresistive memory according to a first embodiment. The magnetoresistive memory is used as a cell of an MRAM and is configured to include a magnetoresistance element and switching transistor.

An STI (Shallow Trench Isolation) region 12 used for element isolation is formed in a silicon substrate 11. In an element formation region surrounded by the STI region 12, a switching MOS transistor 10 is formed. That is, a gate electrode 14 is formed above the silicon substrate 11 with a gate insulating film 13 disposed therebetween and source/drain regions 15 are formed by diffusing an impurity into the surface portion of the substrate to sandwich the gate electrode 14.

In FIG. 1, WL used as the gate electrode 14 extends in the horizontal direction of the drawing sheet and the cross section taken along the gate width direction is shown. Therefore, the source region lies on the back surface side of the drawing sheet and the drain region lies on the front surface side of the drawing sheet.

Further, the switching MOS transistor 10 is not limited to the structure shown in FIG. 1 and may include an embedded gate electrode having a gate electrode embedded in a groove formed in the silicon substrate 11.

Interlayer insulating films 21, 24 are formed on the substrate having the switching MOS transistor 10 formed thereon. In the interlayer insulating film 21, a contact plug 22 and first wire 23 connected to the source of the MOS transistor 10 are formed. Further, a contact plug 25 connected to the drain of the MOS transistor 10 is formed in the interlayer insulating films 21, 24.

Specifically, an interlayer insulating film 21 is deposited on a substrate 11 having a switching MOS transistor 10 formed thereon and the upper surface of the interlayer insulating film 21 is made flat by use of a CMP method or the like. As a material of the interlayer insulating film 21, for example, a boron phosphorus silicate glass (BPSG), plasma-tetraethoxysilane (P-TEOS) and the like can be used.

Then, the interlayer insulating film 21 is selectively removed, a contact hole to be connected to the source region of the switching transistor 10 is formed and a groove for a first wire is formed to be connected to the contact hole. Subsequently, the contact hole and the groove are filled with a metal material to make the surface flat and thus a contact plug 22 and first wire (source line SL) 23 are formed. As a material of the contact plug 22 and first wire 23, for example, W, Ti, N, Cu and the like are used.

Next, after an interlayer insulating film 24 is deposited, a contact hole to be connected to the drain region of the switching MOS transistor 10 is formed. Then, the contact hole is filled with a metal material to form a contact plug 25.

A first ferromagnetic layer 31 is formed on the interlayer insulating film 24 to be connected to the contact plug 25. A nonmagnetic layer 32 and second ferromagnetic layer 33 are laminated on the ferromagnetic layer 31. Further, a third ferromagnetic layer 35 is formed on a part of the second ferromagnetic layer 33 with a tunnel barrier layer 34 disposed therebetween. That is, a five-layered magnetoresistance element 30 formed of the layers 31 to 35 is formed.

Specifically, after the laminated structure of the magnetoresistance element 30 is formed, a first hard mask is formed on the magnetoresistance element 30. Then, the third ferromagnetic layer 35 and tunnel barrier layer 34 are processed. Further, after a second hard mask larger than the first hard mask is formed, the second ferromagnetic layer 33, nonmagnetic layer 32 and first ferromagnetic layer 31 are processed. As a processing method, an RIE method or IBE method is used.

Thus, in this embodiment, the operation of processing the third ferromagnetic layer 35 to the tunnel barrier layer 34 and the operation of processing the second ferromagnetic layer 33 to the first ferromagnetic layer 31 are performed by use of two masks. The order of the operation of processing the third ferromagnetic layer 35 and tunnel barrier layer 34 and the operation of processing the second ferromagnetic layer 33, nonmagnetic layer 32 and first ferromagnetic layer 31 may be reversed.

The materials of the respective portions of the magnetoresistance element 30 are not particularly limited. For example, the ferromagnetic layers 31, 33, are CoFeB, the nonmagnetic layer 32 is Cu and the tunnel barrier layer 34 is MgO.

One of the ferromagnetic layers 31, 33, 35 whose magnetization direction is fixed is called a fixed layer and a layer whose magnetization direction is reversed according to an external magnetic field or STT is called a free layer. The ferromagnetic layers 31 and 35 are fixed layers and the ferromagnetic layer 33 is a free layer. The layers 31 to 33 form a structure (spin valve structure portion) 100 that is called a spin valve having a nonmagnetic layer sandwiched between ferromagnetic layers. The layers 33 to 34 form a structure (tunnel magnetic junction structure portion: MTJ portion) 200 that is called a tunnel magnetic junction. The layers 31 to 35 of the magnetoresistance element 30 form a CCP (Current Perpendicular to Plane)-GMR structure. For example, the resistance of the layers 31 to 33 is 10Ω and the resistance of the layers 31 to 35 is 20 kΩ.

A protection film 41 is formed to cover the magnetoresistance element 30. The protection film 41 is used for suppressing oxidation and reduction of the magnetoresistance element 30 and is formed of, for example, SiN, AL₂O₃ or the like.

A contact plug (read electrode) 42 is formed to be connected to the third ferromagnetic layer 35 through the protection film 41. The contact plug 42 is connected to a bit line (BL) 45 used as a data line. A contact plug (write electrode) 43 is formed to be connected to the second ferromagnetic layer 33 through the protection film 41. The contact plug 43 is connected to a write line 46.

Although not shown in the drawing, the contact plugs 42, 43 and wires 45, 46 are formed after the interlayer insulating film is deposited and made flat. Specifically, after a contact hole connected to the third ferromagnetic layer 35 and a contact hole connected to the second ferromagnetic layer 33 are formed in the interlayer insulating film, metal films are filled therein to form contact plugs 42, 43. Then, the wires 45, 46 respectively connected to the contact plugs 42, 43 are formed. As the contact plugs 42, 43 and wires 45, 46, Cu or W is used.

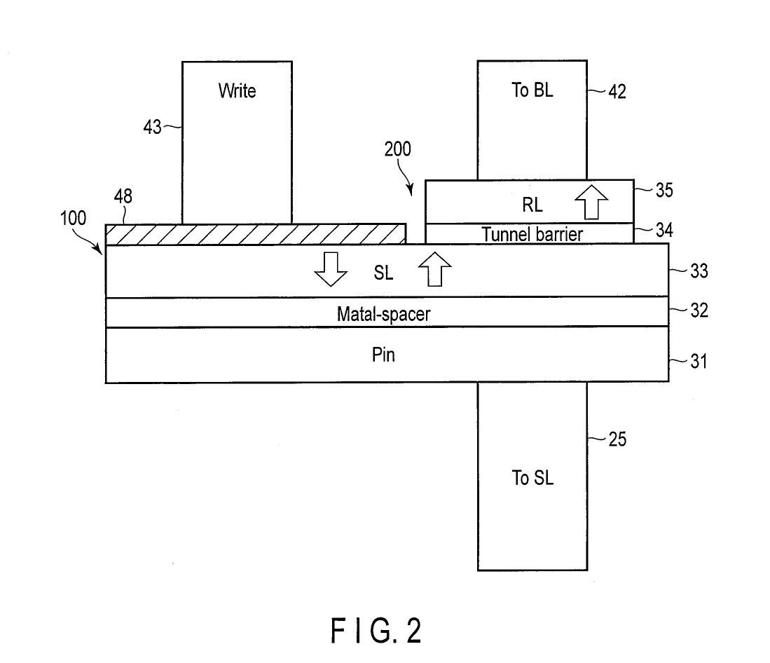

In the magnetoresistance element 30 used in this embodiment, as shown in FIG. 2, the area of a region other than a region in which the MTJ portion 200 is formed on the spin valve structure portion 100 is larger than the area of the region in which the MTJ portion 200 is formed.

In the case of writing, there occurs a possibility that no current flows in a region directly under the MTJ portion 200 of the second ferromagnetic layer 33. However, if the area of the region other than the region in which the MTJ portion 200 is formed is made larger than the area of the region in which the MTJ portion 200 is formed, a current flows in a large area of the second ferromagnetic layer 33 and the magnetization direction in the whole portion of the second ferromagnetic layer 33 can be easily reversed. In this case, if an easy-conduction layer 48 of, for example, Cu having an area larger than that of the contact plug 43 and having a resistance lower than that of the second ferromagnetic layer 33 is formed between the contact plug 43 and the second ferromagnetic layer 33, the magnetization direction of the second ferromagnetic layer 33 at the write time can be further easily reversed.

Next, the write operation and read operation of this embodiment are explained.

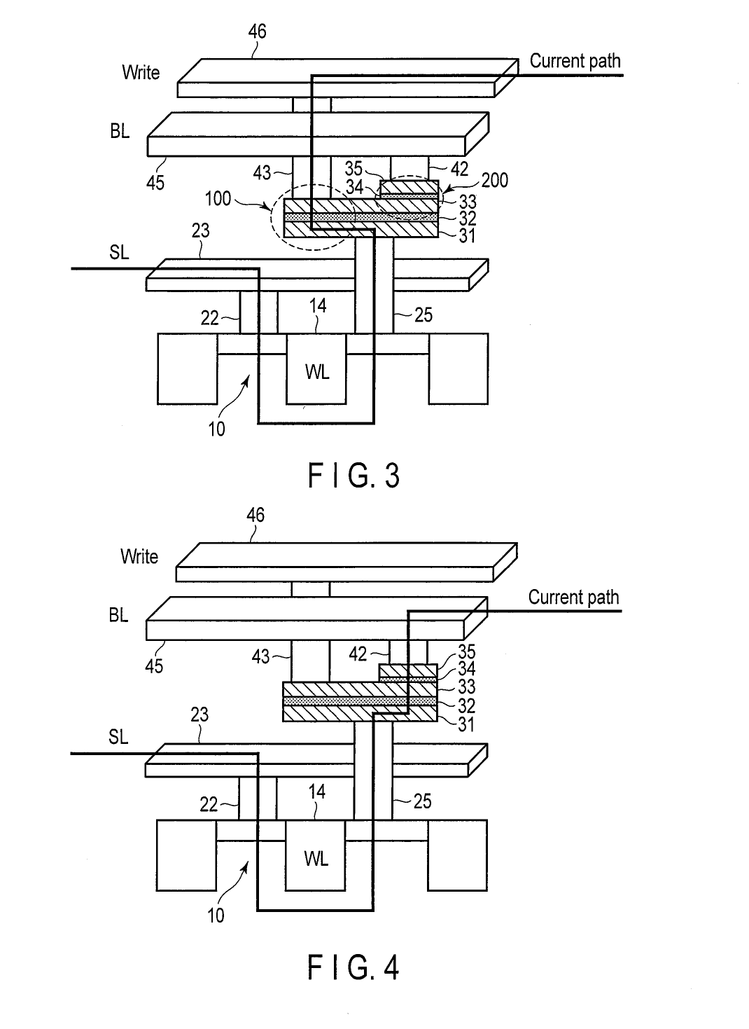

As shown in FIG. 3, in the write operation, a current is passed through a path between the write line 46 and SL 23. Therefore, the second ferromagnetic layer 33, nonmagnetic layer 32, first ferromagnetic layer 31, contact plug 25 and MOS transistor 10 are used as a conduction path.

As shown in FIG. 4, in the read operation, a current is passed through a path between the BL 45 and SL 23. Therefore, the third ferromagnetic layer 35, tunnel barrier layer 34, second ferromagnetic layer 33, nonmagnetic layer 32, first ferromagnetic layer 31, contact plug 25 and MOS transistor 10 are used as a conduction path.

That is, unlike the read operation, in the write operation, a current can be passed through the second ferromagnetic layer 33 without passing the current through the tunnel barrier layer 34. In FIG. 3 and FIG. 4, a case wherein the switching MOS transistor 10 includes an embedded gate electrode is explained.

Thus, in the write operation, since the tunnel barrier layer 34 of the magnetoresistance element 30 is not contained in the current path, the resistance of the magnetoresistance element 30 for writing is low and is 10Ω, for example. Thus, the resistance becomes 1/10000 times the resistance of 10 kΩ in the case of the conventional 2-terminal element. For example, in a 1-Gb MRAM, since the resistance of a portion other than the MTJ is 10 kΩ, the total resistance (20 kΩ (10 kΩ+10 kΩ)→10.01 kΩ (10 kΩ+10Ω)) is approximately halved. As a result, the write current is doubled.

Further, in the case of the conventional 2-terminal element, it is necessary to reduce the resistance of the barrier layer with scaling of the MRAM for the purpose of stably acquiring a sufficient write current. As a result, it becomes necessary to reduce the film thickness of the tunnel barrier layer 34, thereby causing the reliability of the tunnel barrier layer and MR to be degraded.

On the other hand, in this embodiment, since the write terminal is independent, it is unnecessary to pay any attention to the write current in designing the resistance of the tunnel barrier layer 34. As a result, the film thickness that does not cause the reliability of the tunnel barrier layer and MR to be degraded can be set. Further, the film thickness of the tunnel barrier layer 34 can be increased. Thus, the width of “1” and “0” signals can also be increased. For example, when MR is 100%, the resistances of the conventional 2-terminal element are respectively set to 10 kΩ and 20 kΩ in the low-resistance state and high-resistance state. The difference is 10 kΩ. Since the resistance can be increased in the case of the 3-terminal element as in this embodiment, the resistance can be respectively set to 20 kΩ and 40 kΩ in the low-resistance state and high-resistance state and, as a result, the difference becomes 20 kΩ. That is, the signal width can be doubled in comparison with the conventional case.

Thus, according to the present embodiment, the magnetoresistance element 30 is configured by use of the spin valve structure portion 100 and MTJ portion 200 and the write terminal and read terminal are independently provided, and therefore, the apparent element resistance at the write operation time can be reduced. As a result, the drive current can be increased. That is, a sufficiently large write current can be stably attained.

Since it becomes unnecessary to reduce the resistance of the tunnel barrier layer 34 to stably attain a sufficient write current, it becomes unnecessary to reduce the film thickness of the tunnel barrier layer 34 and the reliability of the tunnel barrier layer 34 can be enhanced. Further, since the tunnel barrier layer 34 is made thick to increase the resistance, an advantage that a signal amount at the read time can be increased is attained.

That is, by use of the 3-terminal element, three problems of MRAM scaling can be solved and a large-capacity MRAM can be realized with high yield.

### Second Embodiment

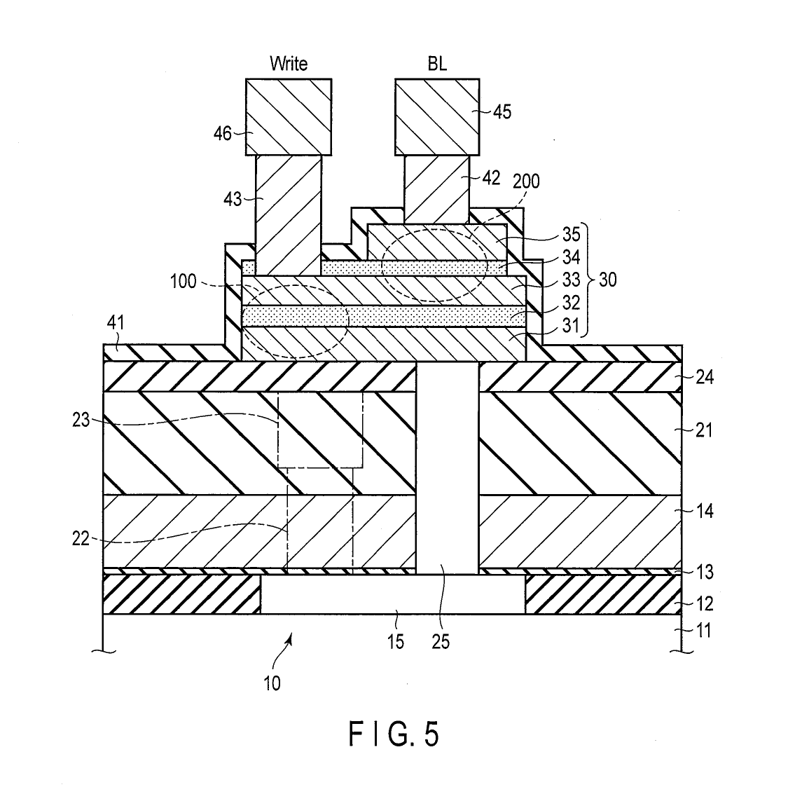

FIG. 5 is a cross-sectional view showing the schematic configuration of a magnetoresistive memory according to a second embodiment. Portions that are the same as those of FIG. 1 are denoted by the same symbols and the detailed explanation thereof is omitted.

This embodiment is different from the first embodiment described before in the configuration of the tunnel barrier layer 34 of the MTJ portion 200. That is, in the first embodiment, the tunnel barrier layer 34 is processed together with the third ferromagnetic layer 35. However, in this embodiment, the tunnel barrier layer 34 is left behind on the second ferromagnetic layer 33 and only the third ferromagnetic layer 35 is processed at the processing time of the MTJ portion 200. Then, a contact plug 43 is formed to make contact with the second ferromagnetic layer 33 via the tunnel barrier layer 34.

With the above configuration, if the contact plug 43 is formed to make direct contact with the second ferromagnetic layer 33, a current path at the write time becomes substantially the same as that of the first embodiment. Therefore, the same effect as that of the first embodiment can be obtained.

Since the resistance of the tunnel barrier layer 34 is extremely larger than that of the third ferromagnetic layer 33, there occurs no problem even if the contact plug 43 is formed to make contact with the tunnel barrier layer 34.

### Third Embodiment

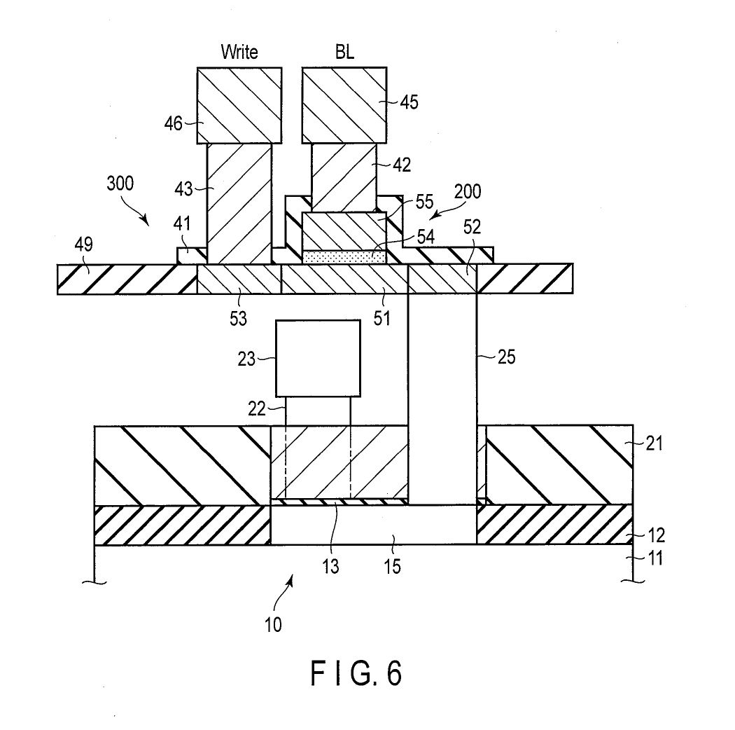

FIG. 6 is a cross-sectional view showing the schematic configuration of a magnetoresistive memory according to a third embodiment and the cell portion is configured by use of a magnetoresistance element and switching MOS transistor as in the first embodiment. Portions that are the same as those of FIG. 1 are denoted by the same symbols and the detailed explanation thereof is omitted.

In this embodiment, a film (domain wall motion structure portion) 300 based on current-induction domain wall motion (Domain wall motion) is used instead of the spin valve structure portion 100 provided in the first embodiment.

Like the first embodiment, a first ferromagnetic layer 51 and second and third ferromagnetic layers 52 and 53 that are formed in contact with both side surfaces of the layer 51 are formed on a substrate on which a switching MOS transistor 10 and contact plug 25 are formed. The ferromagnetic layer 52 is connected to the contact plug 25 on the substrate side and the ferromagnetic layer 53 is connected to a contact plug 43 on the write side. A fourth ferromagnetic layer 55 is formed above the ferromagnetic layer 51 with a tunnel barrier layer 54 disposed therebetween. The fourth ferromagnetic layer 55 is connected to a contact plug 42 on the read side.

In this case, the tunnel barrier layer 54 and fourth ferromagnetic layer 55 are formed not on the whole portion but on a part of the first ferromagnetic layer 51 and the edges of the tunnel barrier layer 54 and fourth ferromagnetic layer 55 are offset with respect of the edge of the first ferromagnetic layer 51. That is, the edges of the tunnel barrier layer 54 and fourth ferromagnetic layer 55 are inwardly set back with respect to the edge of the first ferromagnetic layer 51.

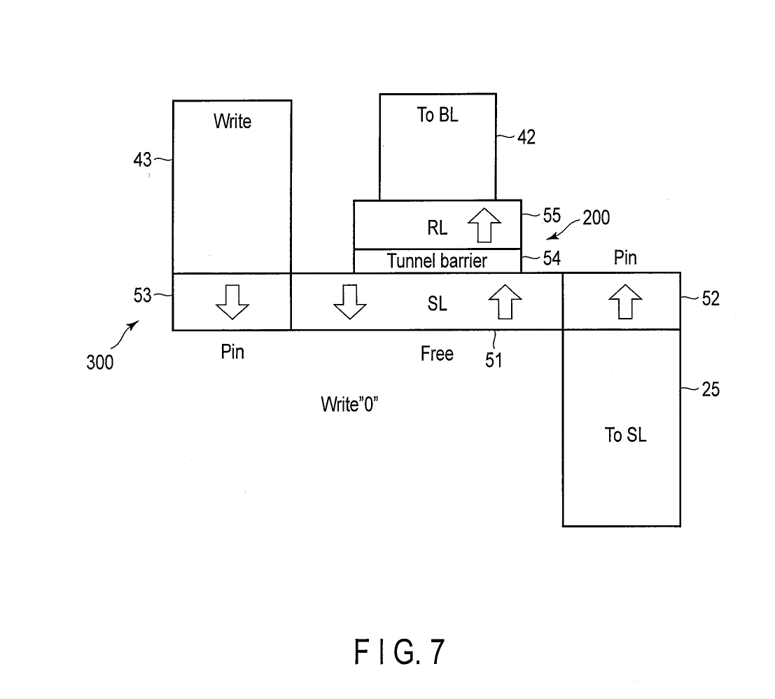

As shown in FIG. 7, the ferromagnetic layer 52 connected to the contact plug 25 and the ferromagnetic layer 53 connected to the contact plug 43 are each formed of a Pin layer and magnetically fixed in the domain wall motion structure portion 300 of this embodiment. The magnetization directions of the above layers are opposite to each other. Further, the ferromagnetic layer 51 formed directly under the tunnel barrier layer 54 is used as a free layer (SL). With this configuration, the magnetization direction of the free layer 51 can be changed based on the motion of the domain wall according to the direction of a current flowing through a path between the contact plugs 25 and 43.

Next, the write operation and read operation in this embodiment are explained.

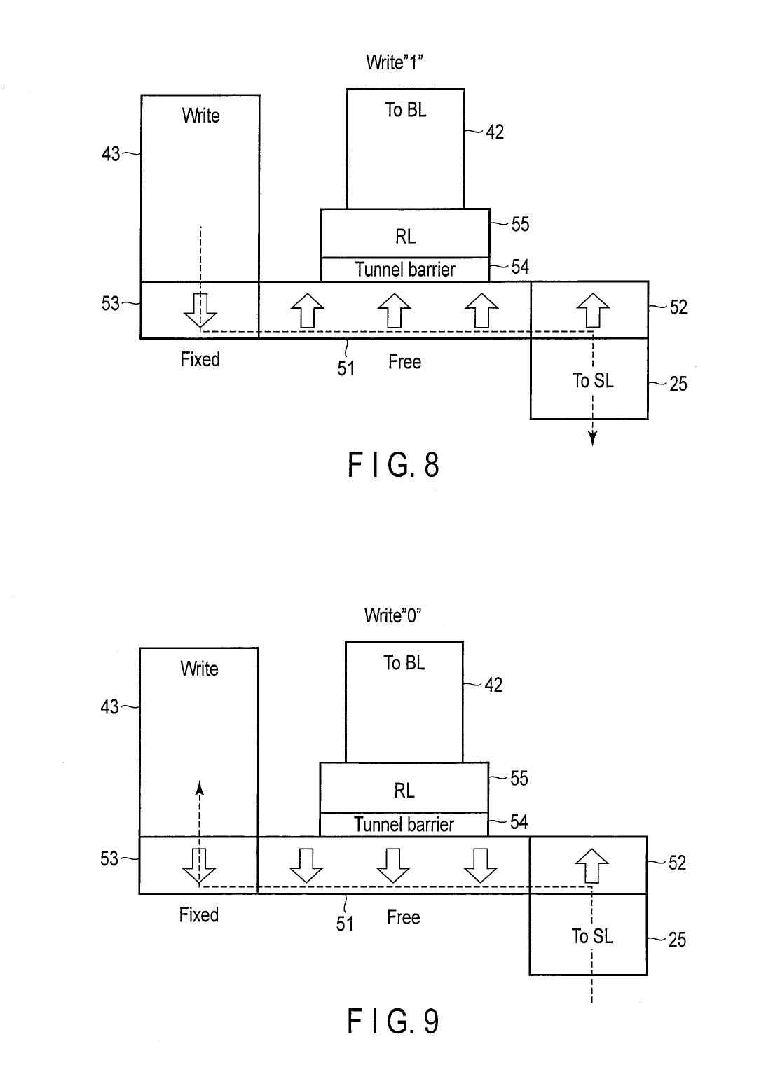

As shown in FIG. 8 and FIG. 9, in the write operation, a current is passed through a path between the contact plugs 43 and 25 and the third ferromagnetic layer 53, first ferromagnetic layer 51 and second ferromagnetic layer 52 are used as a conduction path.

For example, in the “1” write operation, a current is passed in a direction from the third ferromagnetic layer 53 to the second ferromagnetic layer 52 to set the magnetization direction of the first ferromagnetic layer 51 upward. Further, in the “0” write (erase) operation, a current is passed in a direction from the second ferromagnetic layer 52 to the third ferromagnetic layer 53 to set the magnetization direction of the first ferromagnetic layer 51 downward.

In the read operation, a current is passed through the path between the contact plugs 42 and 25 and the fourth ferromagnetic layer 55, tunnel barrier layer 54, first ferromagnetic layer 51 and second ferromagnetic layer 52 are used as a current path.

That is, unlike the read operation, in the write operation, a current can be passed through the first ferromagnetic layer 51 without passing a current through the tunnel barrier layer 54. In other words, in the write operation, since the tunnel barrier layer 54 of the magnetoresistance element 30 is not contained in the current path, the resistance of the element portion is low and is 10Ω, for example. Thus, like the first embodiment, the write current is increased.

According to this embodiment, the magnetoresistance element 30 is configured by use of the domain wall motion structure portion 300 and tunnel magnetic junction structure portion 200 and the write terminal and read terminal are independent, and therefore, the element resistance at the write time can be reduced. Therefore, the same effect as that of the first embodiment can be attained. Further, since the edges of the tunnel barrier layer 54 and fourth ferromagnetic layer 55 are offset with respect to the edge of the first ferromagnetic layer 51, an advantage that shorting between the contact plug 43 and the fourth ferromagnetic layer 55 can be previously prevented is attained.

### Fourth Embodiment

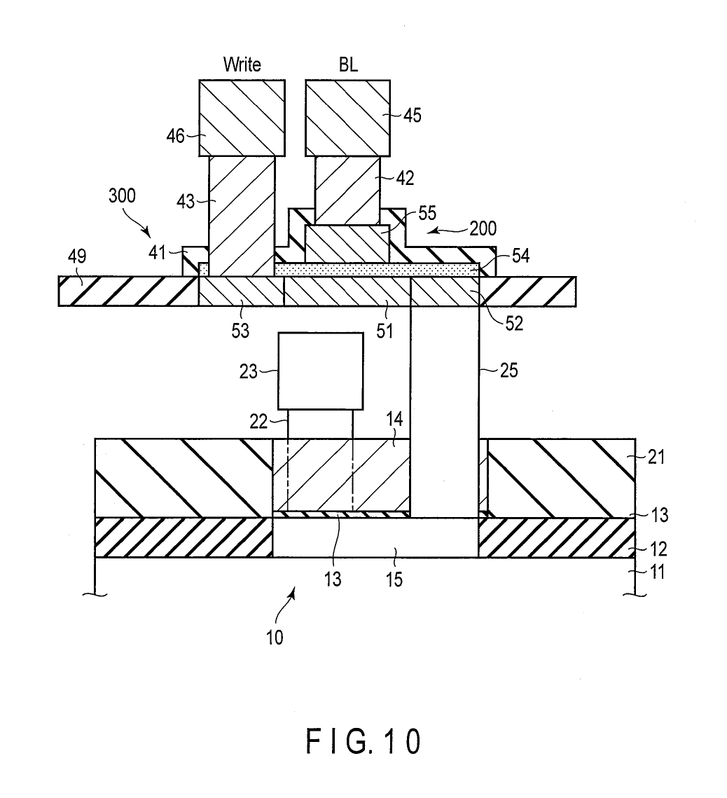

FIG. 10 is a cross-sectional view showing the schematic configuration of a magnetoresistive memory according to a fourth embodiment. Portions that are the same as those of FIG. 6 are denoted by the same symbols and the detailed explanation thereof is omitted.

This embodiment is different from the third embodiment described before in the configuration of the tunnel barrier layer 54 of the MTJ portion 200. That is, in the third embodiment, the tunnel barrier layer 54 is processed together with the fourth ferromagnetic layer 55. However, in this embodiment, the tunnel barrier layer 54 is left behind on the first to third ferromagnetic layers 51, 52, 53 and only the fourth ferromagnetic layer 55 is processed at the processing time of the MTJ portion 200. Then, a contact plug 43 is formed to make contact with the third ferromagnetic layer 53 through the tunnel barrier layer 34.

With the above configuration, if the contact plug 43 is formed in direct contact with the third ferromagnetic layer 53, a current path at the write time becomes substantially the same as that of the third embodiment. Therefore, the same effect as that of the third embodiment can be obtained.

Since the resistance of the tunnel barrier layer 54 is much larger than that of the ferromagnetic layer 51, there occurs no problem even if the contact plug 43 is formed to make contact with the tunnel barrier layer 54.

### Fifth Embodiment

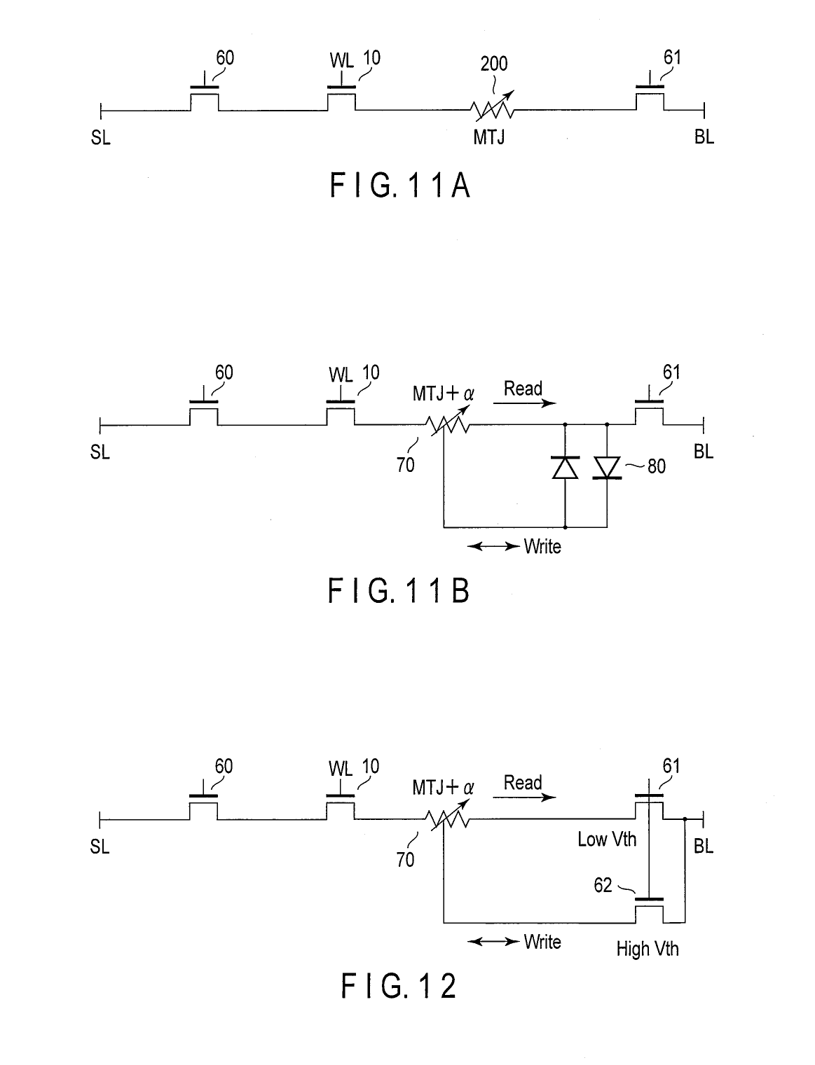

FIGS. 11A, 11B are circuit configuration diagrams for illustrating a magnetoresistive memory according to a fifth embodiment. FIG. 11A shows a case of a 2-terminal MTJ for comparison and FIG. 11B shows a case wherein a 3-terminal MTJ+α of this embodiment is used.

As shown in FIG. 11A, in the 2-terminal element, a column selection transistor 60, 61 are arranged in addition to source line SL, bit line BL and word line WL. That is, one end of an MTJ portion 200 is connected to SL via a switching MOS transistor 10 and column selection transistor 60. The other end thereof is connected to BL via a column selection transistor 61.

As shown in FIG. 11B, in the 3-terminal element, a write line is additionally provided. That is, a bi-directional diode 80 is connected between the write terminal and the read terminal of a magnetoresistance element 70 including an MTJ portion. As is explained in the first and second embodiments, as the magnetoresistance element 70, an element having the MTJ portion 200 formed on the spin valve structure portion 100 can be used. Further, as is explained in the third and fourth embodiments, an element having the MTJ portion 200 formed on the domain wall motion structure portion 300 can also be used.

The threshold voltage of the diode 80 is approximately 0.6 V, the voltage between SL-BL is low at the read operation time and only a voltage (for example, 0.05 V) that is lower than the threshold voltage is applied to the diode 80. Therefore, no current flows in the diode 80 at the read operation time. Therefore, the read operation can be performed like the normal read operation.

On the other hand, since the voltage between SL-BL is high at the write operation time and a voltage (for example, 1.5 V) that is higher than the threshold voltage is applied to the diode 80, a current flows in the diode 80. As a result, the apparent element resistance at the write operation time can be made low and a sufficiently large write current can be passed. Therefore, like the first to fourth embodiments, it is possible to obtain an effect that a sufficient write current can be stably attained, the reliability of the tunnel barrier layer can be enhanced and the signal amount at the read time can be increased.

Thus, according to this embodiment, the write terminal and the read terminal of the 3-terminal magnetoresistance element 70 are connected to each other by means of the bi-directional diode 80. Therefore, the same effect as that of the first to fourth embodiments can of course be obtained, a wire for the write terminal becomes unnecessary and an increase in the area of the peripheral circuit can be suppressed to the minimum.

### Sixth Embodiment

FIG. 12 is a circuit configuration diagram for illustrating a magnetoresistive memory according to a fifth embodiment. Portions that are the same as those of FIG. 11B are denoted by the same symbols and the detailed explanation thereof is omitted.

This embodiment is different from the fifth embodiment described before in that a different column selection transistor 62 having a gate in common with the column selection transistor 61 is provided between the write terminal and BL instead of providing the bi-directional diode. In this case, the transistor 62 connected to the write line is designed to have a threshold voltage higher than that of the transistor 61.

With the above configuration, if the gate voltage of the transistors 61, 62 is adequately set, only the transistor 62 can be turned on at the read time and the transistors 61, 62 can be turned on at the write time. As a result, since no current flows in the transistor 62 at the read time, the read operation can be performed like the normal read operation. On the other hand, since a current flows in the transistor 62 at the write time, the apparent element resistance at the write operation time can be made low and a larger write current can be passed.

Therefore, like the fifth embodiment, the read and write operations can be performed and the same effect as that of the fifth embodiment can be obtained.

### MODIFICATION

The invention is not limited to the above embodiments.

In the first and second embodiments, the magnetoresistance element is formed to have a five-layered structure, but the layer structure of the magnetoresistance element is not always limited to the five layers. For example, a shift cancel layer may be provided between the third ferromagnetic layer 35 and the contact plug 42 or between the first ferromagnetic layer 31 and the contact plug 25. Further, shift cancel layers may be provided in both of the corresponding portions.

The materials of the respective portions are not limited to those described in the above embodiments and can be adequately modified according to the specification. The tunnel barrier layer is not limited to MgO and AlN, AlON, Al₂O₃ or the like can be used. Further, as the nonmagnetic layer, MGO can be used instead of Cu.

The configuration of the magnetoresistance element in the fifth and sixth embodiments is not necessarily limited to the configuration of the first to fourth embodiments and it is sufficient if a 3-terminal structure having a write electrode in addition to the electrode connected to the source line and the read electrode connected to the bit line is provided. In this case, the write electrode is an electrode used for performing the write operation by use of a current path different from the current path at the read operation time.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetoresistance element comprising:
a spin valve structure portion formed on a substrate, the spin valve structure portion being formed by having a nonmagnetic layer sandwiched between first and second ferromagnetic layers,
a tunnel magnetic junction structure portion formed on a part of the spin valve structure portion, the tunnel magnetic junction structure portion including the second ferromagnetic layer, a tunnel barrier layer formed on the second ferromagnetic layer and a third ferromagnetic layer formed on the tunnel barrier layer, and
electrodes connected to the respective ferromagnetic layers.

2. The element of claim 1, wherein the first ferromagnetic layer is a magnetic fixed layer arranged on the substrate side, the second ferromagnetic layer is a magnetic free layer and the third ferromagnetic layer is a magnetic fixed layer.

3. The element of claim 2, wherein the substrate includes a switching MOS transistor and a contact plug that is connected to one of source and drain regions of the transistor and led out on the upper surface of the substrate, an undersurface side of the first ferromagnetic layer is connected to the contact plug, a write electrode is connected to an upper surface side of the second ferromagnetic layer and a read electrode is connected to an upper surface side of the third ferromagnetic layer.

4. The element of claim 3, wherein the tunnel barrier layer is formed on a part of the second ferromagnetic layer.

5. The element of claim 3, wherein the tunnel barrier layer is formed on a portion of the second ferromagnetic layer except a portion on which the write electrode is formed and the third ferromagnetic layer is formed on a part of the tunnel barrier layer.

6. The element of claim 3, wherein an area of a region other than a region in which the tunnel magnetic junction structure portion on the spin valve structure portion is formed is larger than an area of the region in which the tunnel magnetic junction structure portion is formed.

7. The element of claim 6, further comprising an easy-conduction layer that has an area larger than an area of the write electrode in an in-plane direction of the substrate and is formed between the write electrode and the region other than the tunnel magnetic junction structure portion on the second ferromagnetic layer.

8. The element of claim 3, wherein the read electrode is connected to a data line via a select transistor and the write electrode is connected to the read electrode via a bi-directional diode.

9. The element of claim 3, wherein the read electrode is connected to a data line via a first select transistor and the write electrode is connected to the data line via a second select transistor having a threshold voltage higher than that of the first select transistor, a gate being shared between the first and second select transistors.

10. A magnetoresistance element comprising:
a domain wall motion structure portion formed on a substrate, the domain wall motion structure portion including a first ferromagnetic layer formed on the substrate, a second ferromagnetic layer formed in contact with one of side surfaces of the first ferromagnetic layer on the substrate and a third ferromagnetic layer formed in contact with the other side surface of the first ferromagnetic layer on the substrate,
a tunnel magnetic junction structure portion formed on the domain wall motion structure portion, the tunnel magnetic junction structure portion including the first ferromagnetic layer, a tunnel barrier layer formed on the first ferromagnetic layer and a fourth ferromagnetic layer formed on the tunnel barrier layer and an edge of the fourth ferromagnetic layer being inwardly set back with respect to an edge of the first ferromagnetic layer, and
electrodes respectively connected to the second to fourth ferromagnetic layers.

11. The element of claim 10, wherein the first ferromagnetic layer is a magnetic free layer and the second to fourth ferromagnetic layers are magnetic fixed layers.

12. The element of claim 11, wherein the substrate includes a switching MOS transistor and a contact plug that is connected to one of source and drain regions of the transistor and led out on the upper surface of the substrate, an undersurface side of the second ferromagnetic layer is connected to the contact plug, a write electrode is connected to an upper surface side of the third ferromagnetic layer and a read electrode is connected to an upper surface side of the fourth ferromagnetic layer.

13. The element of claim 12, wherein the tunnel barrier layer is formed on a part of the first ferromagnetic layer.

14. The element of claim 12, wherein the tunnel barrier layer is formed on a portion of the first to third ferromagnetic layers except a portion on which the write electrode is formed and the fourth ferromagnetic layer is formed on a part of the tunnel barrier layer.

15. The element of claim 11, wherein magnetization directions of the second and third ferromagnetic layers are opposite to each other.

16. The element of claim 12, wherein the read electrode is connected to a data line via a select transistor and the write electrode is connected to the read electrode via a bi-directional diode.

17. The element of claim 12, wherein the read electrode is connected to a data line via a first select transistor and the write electrode is connected to the data line via a second select transistor having a threshold voltage higher than that of the first select transistor, a gate being shared between the first and second select transistors.

18. A magnetoresistive memory comprising:
a magnetoresistance element of a 3-terminal structure including an electrode for connection with a source line side and read and write electrodes for connection with a bit line side,
a first select transistor connected between the read electrode of the magnetoresistance element and the bit line, and
a write circuit provided in one of a portion between the write electrode of the magnetoresistance element and the bit line or a portion between the write and read electrodes, the write circuit being turned off at a read time and turned on at a write time.

19. The memory of claim 18, wherein the write circuit is a bi-directional diode connected between the write and read electrodes.

20. The memory of claim 18, wherein the write circuit is a second select transistor that is connected between the write electrode and the bit line, has a gate in common with the first select transistor and has a threshold voltage higher than that of the first select transistor.
